(19) United States
(12) Patent Application Publication
(10) Pub. No.: US 2016/0068945 A1
(43) Pub. Date: Mar. 10, 2016

(54) METHOD FOR BEAUTIFYING SURFACE OF REINFORCED GLASS

(71) Applicant: HITEC (TONG XIANG) GLASS & MIRROR CO., LTD., Tong Xiang City (CN)

(72) Inventor: Meng-Chun LIN, New Taipei City (TW)

(21) Appl. No.: 14/482,496

(22) Filed: Sep. 10, 2014

(51) Int. Cl. C23C 14/35

(52) U.S. Cl. CPC C23C 14/35

(57) ABSTRACT

A method for beautifying a surface of a reinforced glass contains steps of: forming a shielding layer on a non-pattern area of a surface of a body of a reinforced glass in an acid resistant ink printing manner or an ink developing manner; plating a dielectric layer on the surface of the body in a vacuum magnetron sputtering manner; plating a metallic isolation layer; plating a metallic reflecting layer, which is colorful or transparent, on a pattern area; plating the metallic isolation layer; plating a protective layer; removing the shielding layer by ways of detergent to form the pattern area on the metallic reflecting layer on the surface of the body. Thereby, the metallic reflecting layer in the pattern area does not oxidize, discolor, and deteriorate in reinforcing process of the body at high temperature, and the pattern area of the metallic reflecting layer does not fade.

### FIELD OF THE INVENTION

The present invention relates to a method for beautifying a surface of a reinforced glass in which a metallic reflecting layer in a pattern area of a body does not oxidize, discolor, and deteriorate in a reinforcing process of the body at high temperature, hence the pattern area does not fade to beautify and reinforce the reinforced glass and to prolong service life of the reinforced glass.

### BACKGROUND OF THE INVENTION

Referring to FIGS. 1 and 2, a conventional reinforced glass contains a body 1, wherein a shielding layer is formed on a non-pattern area 2 of a surface of the body 1 in an acid resistant ink printing manner or an ink developing manner, and a metallic reflecting layer, which is colorful or transparent, is plated on a pattern area 3 of the surface of the body 1 in a vacuum magnetron sputtering manner, the shielding layer is removed by ways of detergent 4 (such as alkaline solvent) to form the pattern area 3 on the metallic reflecting layer on the surface of the body 1, thus beautifying the reinforced glass. However, the pattern area 3 of the metallic reflecting layer oxidizes, discolors, and deteriorates to fade in a reinforcing process of the body at 700° C., so the body 1 is reinforced firstly, and then the pattern area 3 is beautified, thus causing troublesome production and high production cost.

The present invention has arisen to mitigate and/or obviate the afore-described disadvantages.

### SUMMARY OF THE INVENTION

The primary objective of the present invention is to provide a method for beautifying a surface of a reinforced glass in which a metallic reflecting layer in a pattern area of a body does not oxidize, discolor, and deteriorate in a reinforcing process of the body at high temperature, hence the pattern area does not fade to beautify and reinforce the reinforced glass and to prolong service life of the reinforced glass.

To obtain the above, a method for beautifying a surface of a reinforced glass provided by the present invention contains steps of:

forming a shielding layer on a non-pattern area of a surface of a body of a reinforced glass in an acid resistant ink printing manner or an ink developing manner;

plating a dielectric layer on the surface of the body in a vacuum magnetron sputtering manner;

plating a metallic isolation layer;

plating a metallic reflecting layer, which is colorful or transparent, on a pattern area;

plating the metallic isolation layer;

plating a protective layer;

removing the shielding layer by ways of detergent to form the pattern area on the metallic reflecting layer on the surface of the body.

Thereby, the pattern area, in which the metallic reflecting layer is formed, is not corroded by sodium and oxygen by using the dielectric layer and the metallic isolation layer. In addition, the protective layer enhances mechanical and chemical stability of the metallic reflecting layer. Preferably, the metallic reflecting layer in the pattern area of the body does not oxidize, discolor, and deteriorate in the reinforcing process of the body at high temperature, hence the pattern area does not fade to beautify and reinforce the reinforced glass and to prolong service life of the reinforced glass.

The dielectric layer is made of oxide or nitride, such as any one of Si3N4, Si3N4+TiO2, and TiO2.

The metallic isolation layer is made of any one of NiCrOx, NiCrNx, and NiCr.

The protective layer is made of Si3N4 or Si3N4+TiO2/TiO2.

When the metallic reflecting layer with patterns is reinforced, the metallic isolation layer is not plated on the metallic reflecting layer.

The dielectric layer, the metallic isolation layer, and the protective layer protect and reinforce the reinforced glass, when the reinforced glass is not reinforced.

The dielectric layer, the metallic isolation layer, and the protective layer are transparent.

### BRIEF DESCRIPTION OF THE DRAWINGS

FIG. 1 is a perspective view showing the assembly of a conventional reinforced glass.

FIG. 2 is another perspective view showing the assembly of the conventional reinforced glass.

FIG. 3 is a flow chart of a method for beautifying a surface of a reinforced glass according to a preferred embodiment of the present invention.

FIG. 4 is a perspective view showing the assembly of a reinforced glass with a beautified surface according to the preferred embodiment of the present invention.

FIG. 5 is a cross sectional view showing the assembly of the reinforced glass with the beautified surface according to the preferred embodiment of the present invention.

### DETAILED DESCRIPTION OF THE PREFERRED EMBODIMENTS

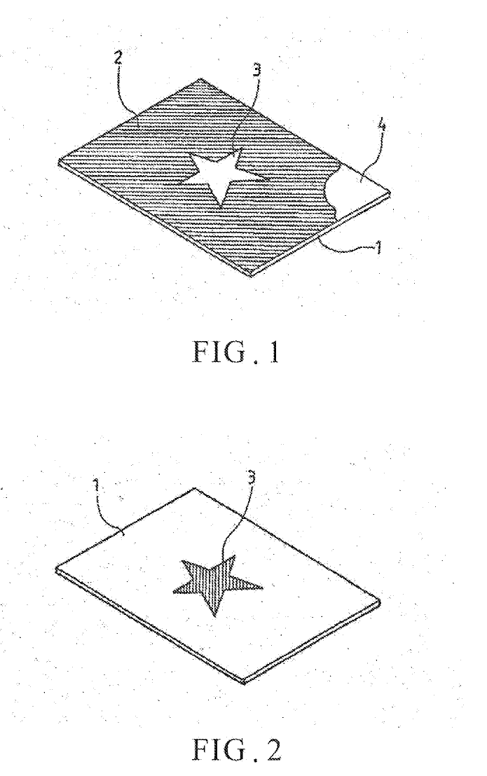

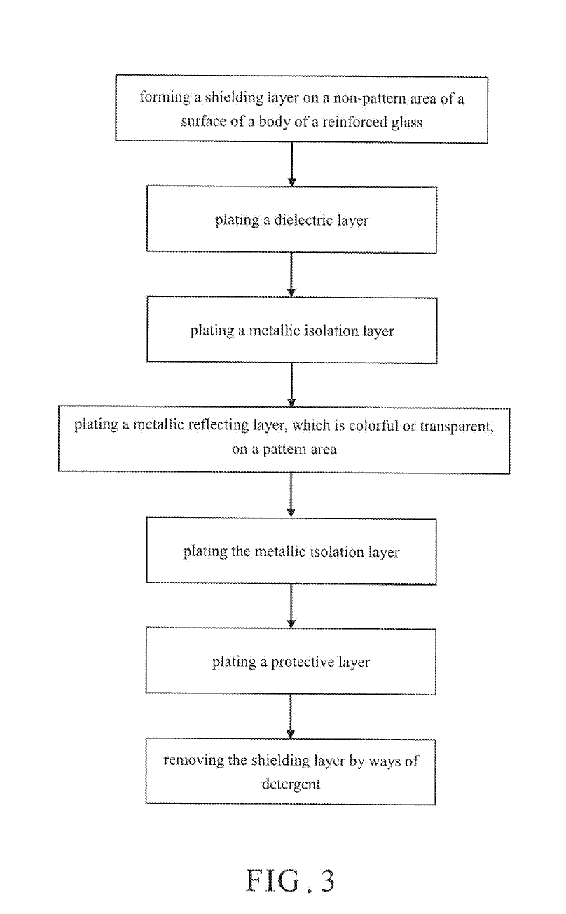

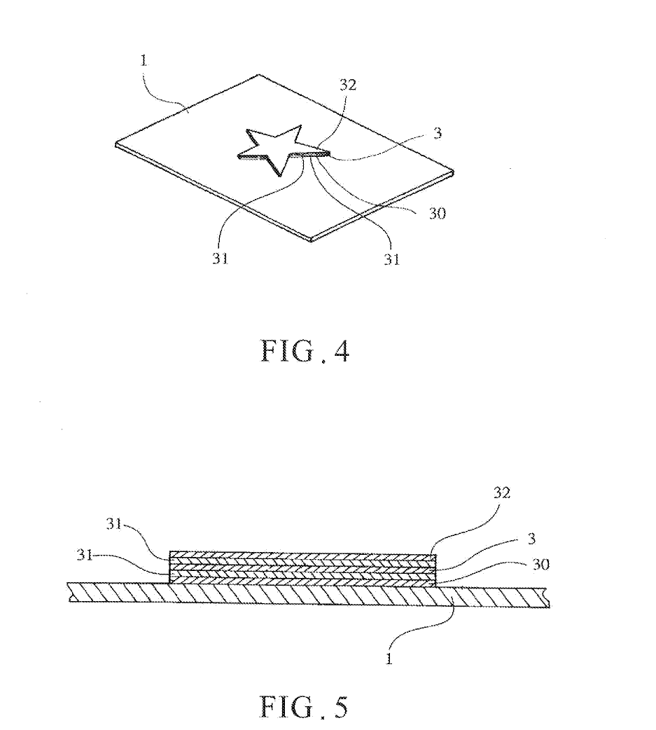

FIG. 3 is a flow chart of a method for beautifying a surface of a reinforced glass according to a preferred embodiment of the present invention. FIG. 4 is a perspective view showing the assembly of a reinforced glass with a beautified surface according to the preferred embodiment of the present invention. FIG. 5 is a cross sectional view showing the assembly of the reinforced glass with the beautified surface according to the preferred embodiment of the present invention. As shown in FIGS. 1 and 2, the method for beautifying the surface of the reinforced glass of the present invention comprises steps of:

1) forming a shielding layer on an non-pattern area 2 of a surface of a body 1 of a reinforced glass in an acid resistant ink printing manner or an ink developing manner;

2) plating a metallic reflecting layer 3 on an non-shielding area 3 of the surface of the body 1 in a vacuum magnetron sputtering manner, wherein the metallic reflecting layer is colorful or transparent;

3) removing the shielding layer by ways of detergent (such as alkaline solvent) to form a pattern area 3 on the metallic reflecting layer 3 on the surface of the body 1.

To avoid oxidation, discoloration, and deterioration of the metallic reflecting layer 3 in reinforcing process of the body 1, the method for beautifying the surface of the reinforced glass of the present invention also comprises steps of:

A) forming a shielding layer on the non-pattern area 2 of the surface of the body 1 of the reinforced glass in the acid resistant ink printing manner or the ink developing manner;

B) plating a dielectric layer 30 on the non-shielding area 3 and the non-pattern area 2 of the surface of the body 1, wherein the dielectric layer 30 is made of oxide or nitride, such as any one of Si3N4, Si3N4+TiO2, and TiO2.

C) plating a metallic isolation layer 31 on a surface of the dielectric layer 30, wherein the metallic isolation layer 31 is made of any one of NiCrOx, NiCrNx, and NiCr.

D) plating the metallic reflecting layer 3, which is colorful or transparent, on the surface of the metallic isolation layer 31, wherein the metallic reflecting layer 3 is made of any one of titanium, stainless steel, nickel, and chromium and their oxides or nitrides.

E) plating the metallic isolation layer 31 on the surface of the metallic reflecting layer 3, wherein the metallic isolation layer 31 is made of any one of NiCrOx, NiCrNx, and NiCr.

F) plating a protective layer 32 on the surface of the metallic isolation layer 31, wherein the protective layer 32 is made of oxide or nitride, such as Si3N4 or Si3N4+TiO2/TiO2.

G) removing the shielding layer by ways of the detergent 4 (such as alkaline solvent).

Thereby, the pattern area 3, in which the metallic reflecting layer 3 is formed, is not corroded by sodium and oxygen by using the dielectric layer 30 and the metallic isolation layer 31. In addition, the protective layer enhances mechanical and chemical stability of the metallic reflecting layer 3.

The metallic reflecting layer 3 in the pattern area 3 of the body 1 does not oxidize, discolor, and deteriorate in the reinforcing process of the body 1 at high temperature, hence the pattern area 3 does not fade to beautify the reinforced glass, prolong service life of the reinforced glass, simplify manufacture, and reduce production cost.

Preferably, when the metallic reflecting layer 3 with patterns is reinforced, the metallic isolation layer 31 is not plated on the metallic reflecting layer 3.

Preferably, the dielectric layer 30, the metallic isolation layer 31, and the protective layer 32 protect and reinforce the reinforced glass, when the reinforced glass is not reinforced.

The dielectric layer 30, the metallic isolation layer 31, and the protective layer 32 are transparent.

Accordingly, the method for beautifying the surface of the reinforced glass can reinforce the reinforced glass easily in post-manufacturing process. Furthermore, the reinforced glass is beautified and reinforced at low production cost and high quality and can avoid fading of the pattern area 3 of the metallic reflecting layer 3.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A method for beautifying a surface of a reinforced glass comprising steps of:
forming a shielding layer on a non-pattern area of a surface of a body of a reinforced glass in an acid resistant ink printing manner or an ink developing manner;
plating a dielectric layer on the surface of the body in a vacuum magnetron sputtering manner;
plating a metallic isolation layer;
plating a metallic reflecting layer, which is colorful or transparent, on a pattern area;
plating the metallic isolation layer;
plating a protective layer;
removing the shielding layer by ways of detergent to form the pattern area on the metallic reflecting layer on the surface of the body.

2. The method for beautifying the surface of the reinforced glass as claimed in claim 1, wherein the dielectric layer is made of Si3N4.

3. The method for beautifying the surface of the reinforced glass as claimed in claim 1, wherein the dielectric layer is made of Si3N4+TiO2.

4. The method for beautifying the surface of the reinforced glass as claimed in claim 1, wherein the dielectric layer is made of TiO2.

5. The method for beautifying the surface of the reinforced glass as claimed in claim 1, wherein the metallic isolation layer is made of NiCrOx.

6. The method for beautifying the surface of the reinforced glass as claimed in claim 1, wherein the metallic isolation layer is made of NiCrNx.

7. The method for beautifying the surface of the reinforced glass as claimed in claim 1, wherein the metallic isolation layer is made of NiCr.

8. The method for beautifying the surface of the reinforced glass as claimed in claim 1, wherein the protective layer is made of Si3N4.

9. The method for beautifying the surface of the reinforced glass as claimed in claim 1, wherein the protective layer is made of Si3N4+TiO2/TiO2.

10. The method for beautifying the surface of the reinforced glass as claimed in claim 1, wherein the detergent is alkaline solvent.

11. The method for beautifying the surface of the reinforced glass as claimed in claim 1, wherein when the metallic reflecting layer with patterns is reinforced, the metallic isolation layer is not plated on the metallic reflecting layer.

12. The method for beautifying the surface of the reinforced glass as claimed in claim 1, wherein the dielectric layer, the metallic isolation layer, and the protective layer protect and reinforce the reinforced glass, when the reinforced glass is not reinforced.

13. The method for beautifying the surface of the reinforced glass as claimed in claim 1, wherein the dielectric layer, the metallic isolation layer, and the protective layer are transparent.
